(19) United States
(12) Patent Application Publication
(10) Pub. No.: US 2023/0005896 A1
(43) Pub. Date: Jan. 5, 2023

(54) WAFER LEVEL CHIP SCALE PACKAGING

(71) Applicant: ams Sensors Asia Pte. Ltd., Singapore (SG)

(72) Inventors: Kam Wah Leong, Singapore (SG); QiChuan Yu, Singapore (SG); Yoong Kheng Teoh, Singapore (SG); Sung Hoe Hng, Singapore (SG); Kyaw Oo Aung, Singapore (SG)

(21) Appl. No.: 17/779,927

(22) PCT Filed: Apr. 29, 2021
(86) PCT No.: PCT/SG2021/050237

§ 371 Date: May 25, 2022

(30) Foreign Application Priority Data
May 15, 2020 (GB) 2007232.8

(51) Int. Cl. H01L 25/16; H01L 33/56; H01L 33/62

(52) U.S. Cl. CPC H01L 25/167; H01L 33/56; H01L 33/62; H01L 2933/005; H01L 2933/0058

(57) ABSTRACT

A method of fabricating one or more optoelectronic devices each comprising at least one passive optical component. The method comprises providing a first carrier, depositing a soluble adhesive onto a surface of the first carrier, and placing a plurality of integrated circuit devices onto said surface and curing the soluble adhesive to fix the integrated circuit devices to the carrier. The method further comprises depositing a molding material onto a plurality of molds of a second carrier to form a plurality of said passive optical components, aligning said first and second carriers such that the plurality of passive optical components contact respective zones of the plurality of integrated circuit devices, injecting a polymer compound into a space between said first and second carriers and curing said polymer compound, removing said second carrier to leave the plurality of optical components fixed to the integrated circuit devices by said polymer compound, and dissolving said soluble adhesive to remove the integrated circuit devices, polymer compound and passive optical components from the first carrier to provide a wafer package.

### TECHNICAL FIELD

The present invention relates to wafer level chip scale packaging and more particularly to such chip scale packaging utilising vacuum injection molding for optoelectronic components.

### BACKGROUND

Traditional integrated circuit (IC) technology utilised bond wires to electrically couple contact pads on a surface of the IC die to external electrical circuitry such as the pins of a dual in-line or flat package. This however puts an unreasonable limit on the number of connections that can be made. To facilitate an increased number of connections, so-called ball grid array packaging (BGA) technologies were introduced. In a typical BGA application, the entire lower surface (often referred as the “front face”) of a device is used to accommodate pads to which solder balls are attached. The pads are coupled to the IC whilst the solder balls in turn allow the device to be secured to, for example, a printed circuit board (PCB) with a matching pattern of copper pads.

In order to further increase the density of interconnection pins, a technology known as Embedded (or Extended) Wafer Level Ball Grid Array (eWLB) has more recently been introduced. eWLB takes advantage of wafer-level packaging (WLP) technology which allows packaging of an integrated circuit whilst still part of the wafer. Unlike WLP however, eWLB, does not create the package on a silicon wafer. Rather, it creates an artificial wafer. A front-end processed silicon wafer is diced and the singulated chips placed on a carrier. In some cases, a mix of singulated chip types are placed together on a carrier. The gaps between the singulated chips on the carrier are filled with a casting compound such that the entire structure forms single artificial wafer containing the multiple singulated chips. By subsequently removing the carrier leaving the encased singulated chips, electrical connections from the chip pads on the front face to the interconnects can be made using, for example, thin-film technology. Connections to interconnect chips to one another can also be provided. The completed artificial wafer can then be diced to provide individual devices. This approach allows for the “fan-out” of connections to a ball grid array, increasing the number of interconnects that can be made between a chip and external circuitry.

Whilst these eWLB technologies work well with many chip types, challenges arise where chips comprise electrical contact pads on a top or “rear” face the chip, either in addition to the pads on the front face or instead of these front face pads. Such rear face pads are often present in the case of optoelectronics chips including chips designed to operate as optical sensors. Chips of this type require so-called two-sided access (TSA) eWLB. U.S. Pat. No. 9,177,884 describes such an access solution and involves growing out metal “stamps” from electrical conductors on the rear faces of the chips prior to singulation. After the chips have been singulated and attached to the carrier, the chips are encapsulated within a polymer mold material. The material is then ground back to expose the various metal stamps which are now all at the same level. Thin film technology is used as with the known eWLB process to extend out the pads on the front face and to interconnect different chips. Holes are drilled through the mold material and the holes filled with a conductive material to electrically connect the extended pads on the front face to the rear face with conductive vias. Solder balls are attached to the tops of the conductive vias (at the rear face) and to the exposed metal stamps, thus creating ball array on the rear face. The artificial wafer can then be diced to provide singulated artificial chips. Chips of this type are referred to as Through Substrate Via (TSV) chips.

Singulated TSV chips may require further packaging, for example in order to incorporate passive optical components such as lenses and light guiding channels. The paper “Selective over-molding of a CMOS TSV wafer with the flexible 3D integration of components and sensors”, Johan Hamelink et al, 2017, 19th Electronics Packaging Technology Conference, describes a process referred to as “film assisted molding and dynamic insert technology” which involves locating a chip between upper and lower molds, whilst using a tool to apply selective pressure to an upper surface zone of the chip which must remain open following molding. With pressure applied by the tool, molten polymer is injected into the space between the two molds and cured to encapsulate the chip whilst leaving the upper surface zone clear of polymer. The process of FIG. 1 is not however well suited to wafer-level production where over-molding is performed on the wafer prior to singulation of the wafer into individual optoelectronic devices.

### SUMMARY

According to a first aspect of the present invention there is provided a method of fabricating one or more optoelectronic devices each comprising at least one passive optical component, for example lenses. The method comprises (a) providing a first carrier, (b) adhering a plurality of integrated circuit devices onto a surface of the first carrier to fix the integrated circuit devices to the first carrier, and (c) depositing an optical molding material onto a plurality of molds of a second carrier. The method further comprises (d) aligning and configuring said first and second carriers such that the optical molding material contacts respective zones of the plurality of integrated circuit devices, (e) curing the optical molding material to form a plurality of said passive optical components attached to said zones, (f) injecting a polymer compound into a space between said first and second carriers and curing said polymer compound, (g) removing said second carrier to leave the plurality of optical components fixed to the integrated circuit devices, and (h) removing the integrated circuit devices, polymer compound and passive optical components from the first carrier to provide a wafer package.

Step (b) may comprise adhering said plurality of integrated circuit devices onto said surface of the first carrier using an adhesive, for example a soluble adhesive, or an adhesive tape. The adhesive may be a water soluble adhesive and the method comprises, following step (h), removing the adhesive, or any residual adhesive, using water.

Following step (h), the wafer package may be sub-divided or diced to provide a plurality of said optoelectronic devices. This may be single component devices, dual component devices (e.g. with emitter and receiver), or multi-component devices.

The plurality of integrated circuits may be mechanically and electrically coupled to a first surface of a planar substrate, for example a silicon substrate, with solder bumps provided on an opposed second surface of the substrate and through substrate vias to provide electrical coupling between the solder bumps and the integrated circuits, and step (b) comprises abutting said second surface against said surface of the first carrier so that the solder bumps are in contact with a soluble adhesive. The surface of the first carrier may define a plurality of wells into which said soluble adhesive is deposited.

Alternatively, the method may comprise, after step (h), attaching the wafer package to a first surface of a Printed Circuit Board, PCB, to provide a composite structure, the PCB being provided with solder bumps on a second, opposed surface of the PCB and through PCB vias for electrically coupling the solder bumps to said first surface and thereby to integrated circuit devices of the wafer package. The method may comprise using a conductive adhesive on conductive pads, provided on said first surface of the PCB, and a non-conductive adhesive on other areas of the first surface, to attach the wafer package to the PCB.

The plurality of integrated circuits may be mechanically and electrically coupled to a first surface of a planar substrate, for example a silicon substrate, with through substrate vias providing electrical coupling between said integrated circuit components and said PCB. After attaching the wafer package to the PCB, the composite structure may be sub-divided or diced to provide a plurality of said optoelectronic devices.

The method may comprise, between steps (g) and (h), scribing said polymer compound between the integrated circuit devices.

The polymer compound may at least partially surround the passive optical components to provide additional mechanical support for those components.

According to a second aspect of the present invention there is provided a discrete optoelectronics device comprising at least one integrated circuit device, a substantially planar substrate having a first surface to which the or each optoelectronics component is fixed, and one or more solder bumps located on a second, opposed surface of the substrate and being electrically coupled to the or each optoelectronics component through said substrate. The device further comprises one or more passive optical components adhered to a surface of the or each integrated circuit device, and a polymer partially surrounding the or each integrated circuit device above the substrate. The polymer may, optionally, provide mechanical coupling of the or each optoelectronics component to the substrate.

The device may comprise two or more passive optical components having different optical properties. For example, the device may comprise two integrated circuit devices, one being a light emitter and one being a light receiver, such that the two integrated circuit devices are held together by said polymer.

The substrate may comprise a silicon substrate with said first and second surfaces being surfaces of the silicon substrate.

The substrate may alternatively comprise a silicon substrate providing said first surface and a Printed Circuit Board, PCB, fixed to an opposed surface of the silicon substrate, said second surface being an opposed surface of the PCB.

According to a third aspect of the present invention there is provided a discrete optoelectronics device produced using the method of the above first aspect of the invention.

### BRIEF DESCRIPTION OF THE DRAWINGS

FIGS. 1a to 1m illustrate a sequence of steps of an improved wafer-level process of over-molding optoelectronics devices with a polymer compound, where the devices are provided on a common wafer with bottom solder bumps;

FIG. 2 illustrates over-molded optoelectronics devices produced using the wafer-level process of FIGS. 1a to 1m;

FIGS. 3a and 3b illustrate schematically wafer fabrication and dicing to provide multiple respective sets of optical emitter and receiver optoelectronics devices;

FIGS. 4a to 4m illustrate a sequence of steps of an improved wafer-level process of over-molding optoelectronics devices with a polymer compound, where the devices each comprise dual components provided initially in singulated form;

FIG. 5 is a flow diagram illustrating an improved wafer-level optoelectronic device over-molding process.

FIGS. 6a to 6g illustrate selected steps of a sequence of steps of an improved wafer-level process of over-molding optoelectronics devices with a polymer compound providing for through PCB vias; and

FIGS. 7a to 7c illustrate selected steps of a sequence of steps of an improved wafer-level process of over-molding optoelectronics devices with a polymer compound providing for through PCB vias, where the devices each comprise dual components provided initially in singulated form.

### DETAILED DESCRIPTION

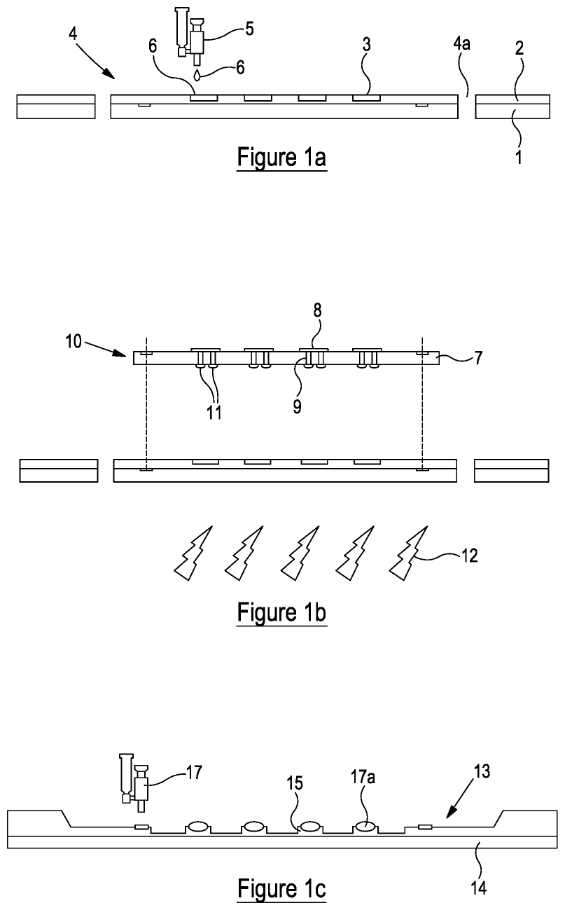

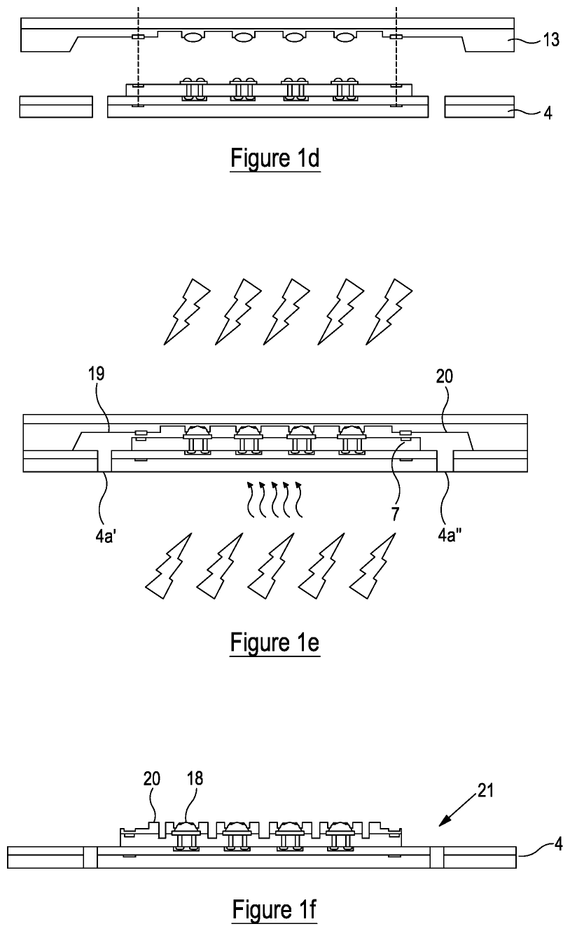

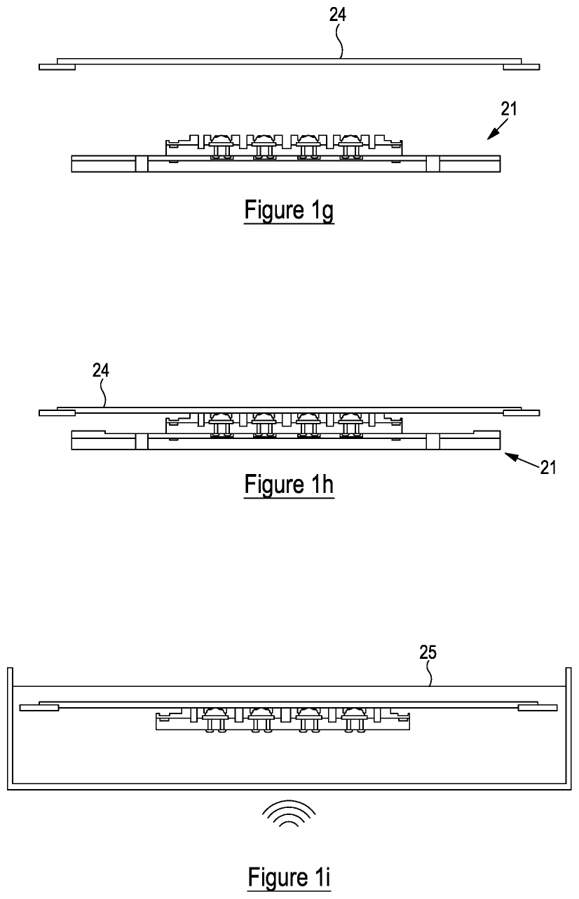

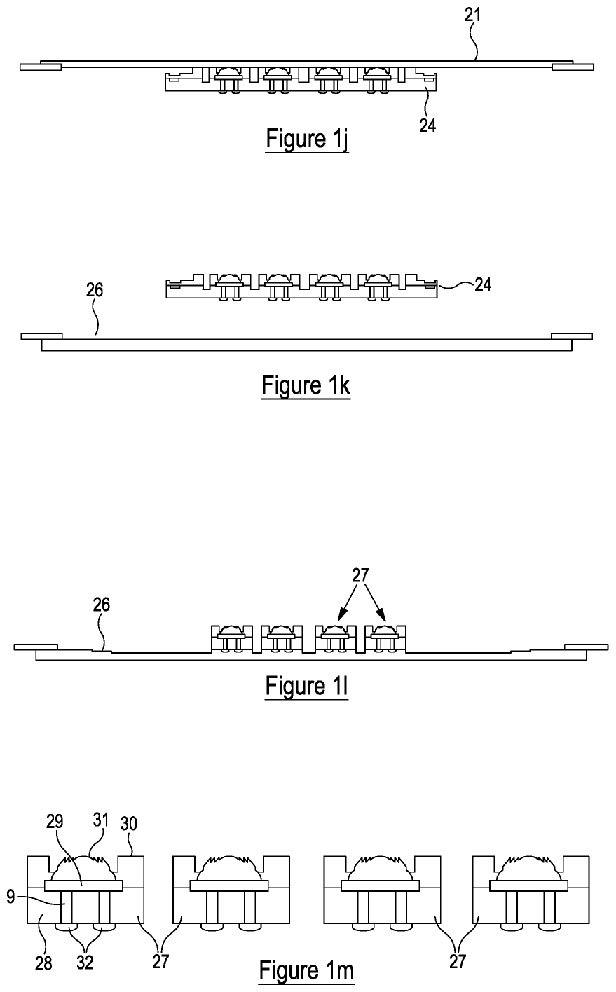

A process for over-molding Through Substrate Via (TSV) chips at the wafer level will now be described. A process applicable to single component on silicon wafer with bottom solder bumps is illustrated in FIGS. 1a to 1m.

FIG. 1a illustrates a planar glass carrier 1 on which is provided a patterned layer of polydimethylsiloxane (PDMS) 2. The pattern may be a one or two dimensional array of wells 3 formed in the PDMS layer 2, e.g. using standard photolithographic techniques. The carrier 1 and PDMS layer 2 are referred to collectively hereinafter as the “first carrier” 4. Holes 4a extend through the first carrier in order to facilitate an injection molding process as will be described further below. FIG. 1a illustrates the use of a jetting tool 5 to inject a water soluble adhesive 6 (for example an epoxy-based adhesive) into each of the wells.

FIG. 1b illustrates a silicon wafer 7 on which are provided a plurality of stacked integrated circuits 8, i.e. the composite structure has the form of the artificial wafer 10 described above. In this example the integrated circuits 8 are optoelectronic components. The optoelectronic components 8 are arranged in an array corresponding to the array of wells provided on the first carrier 4. Solder bumps 11 are provided on the base of the artificial wafer 10 and are coupled to contacts of the optoelectronics components 8 using through substrate vias 9. Only two solder bumps are shown in the figures for illustrative purposes and in practice more or less bumps may be provided. The artificial wafer 10 is lowered onto the first carrier 4 so that the artificial wafer 10 rests on the first carrier 4 with the solder bumps 11 being located in the adhesive filled wells 3. The assembled structure 12 is then exposed to UV radiation 12 to cure the adhesive, fixing the components together.

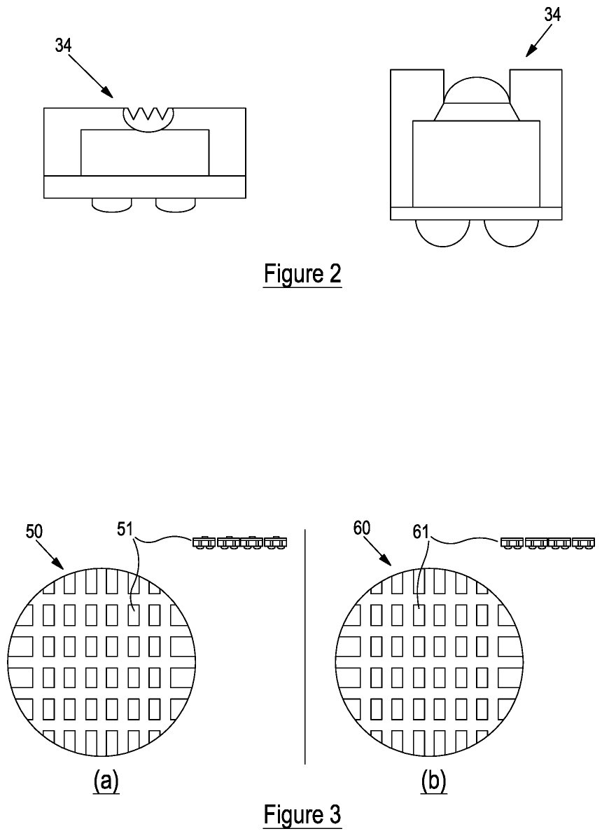

Referring now to FIG. 1c, a separate and parallel process is used to form a set of passive optical components, e.g. lenses, on a carrier. The figure illustrates a lensing tool 13 in the form of a generally planar structure 14 on which are provided an array of lens molds 15. In this example, the array of lens molds has the same size and dimensions as the array of wells 3 and array of optoelectronic components 8, although this need not be the case as will be described further below. The structure of FIG. 2c is referred to hereinafter as the “second carrier” 13.

A jetting tool 17 is used to inject lens forming compound 17a (for example an optically clear epoxy) onto each of the lens molds 15. As is further illustrated in FIG. 1d, the first carrier 4 and the second carrier 13 are brought together, whilst the lens forming compound remains unset, such that the artificial wafer 10 is opposed to the surface of the second carrier on which the lens forming compound 17a is arranged, with the array of lens forming compound being aligned with the array of optoelectronic components 8. The two carriers are then brought into contact with one another as shown in FIG. 1e such that a cavity 19 is formed between the first and second carrier, the holes 4a opening into the cavity. In this state, the lens forming compound 17a will flow to conform to the surfaces of the optoelectronic components with which they contact. The compound 17a is then cured using UV radiation such that the compound forms a plurality of lenses 18. This causes the lenses 18 to become adhered to the surfaces of the respective optoelectronic components 8.

FIG. 1e also illustrates a polymer 20 that has been injected into the cavity 19 via one of the holes 4a′ whilst a vacuum is applied to the other of the holes 4a″, after curing of the lens compound. The polymer may be, for example, an epoxy resin. The polymer is cured under suitable conditions, e.g. using UV radiation followed by heating.

The second carrier 13 is then removed by peeling off the remaining structure 21, leaving the polymer 20 attached to the first carrier 4. A laser is used to etch through the polymer between the optoelectronics devices and also surrounding the wafer 7. This is illustrated in FIG. 1f from which it will be noted that, as the remaining polymer 20 extends around and partially over upper regions of the lenses 18, the lenses are captured by the polymer. This structure may assist in retaining the lenses 18 on the optoelectronics components. In the case of a two dimensional array of components, the cuts in the polymer 20 will extend in two orthogonal directions. These cuts allow subsequent separation of the components as well as stress relief within the composite structure (prior to separation).

A heat resistant tape 24 is then aligned with the structure 21 as shown in FIG. 1g, and subsequently secured on top of the structure as shown in FIG. 1h. The first carrier 4 is then removed from the remaining structure, and that structure is introduced into an ultrasonic water tank 25 in order to dissolve any remaining adhesive. FIG. 1i shows the remaining structure within the ultrasonic tank 25 with the first carrier 4 removed. FIG. 1j shows the remaining structure after removal from the ultrasonic water tank.

As shown in FIG. 1k, the heat resistant tape 24 is removed from the structure and a further, dicing tape 26 fixed to the structure beneath the solder bumps 11. This allows for subsequent dicing, by cutting completely through the wafer 7 as shown in FIG. 1l. The dicing tape 26 is then removed to allow separation of the wafer into a set of singulated optoelectronics devices 27.

FIG. 1m illustrates a set of four such singulated optoelectronic device 27 comprising a silicon carrier 28, optoelectronic component 29, polymer 30, lens 31, and solder bumps 32, as well as the through substrate vias 9. The lens type may be, for example, Fresnel, micro lens array (MLA), diffractive optical element (DOE), etc.

FIG. 2 also illustrates optoelectronic devices 33 and 34 fabricating using the described method and again illustrating that the lens' structures are such that they adhere to the optoelectronic components and are partially surrounded by the polymer and remain fixed to the optoelectronic components when the second carrier is removed.

As indicated above, the lens array 18 and array of optoelectronic components may not have a one-to-one correspondence. For example, two or more lenses and/or other passive optical components may be provided for each optoelectronic component, or passive optical components may not be provided for all optoelectronic components.

Whilst the process described above is in the context of single component optoelectronic devices, a similar process may be used to produce multi-component optoelectronics devices. FIGS. 3a and 3b illustrate respectively a first diced wafer 50 providing a plurality of emitter optoelectronic devices 51 and a second diced wafer 60 providing a plurality of receiver optoelectronic devices 61. Exemplary emitter and receiver devices are also shown in cross-section.

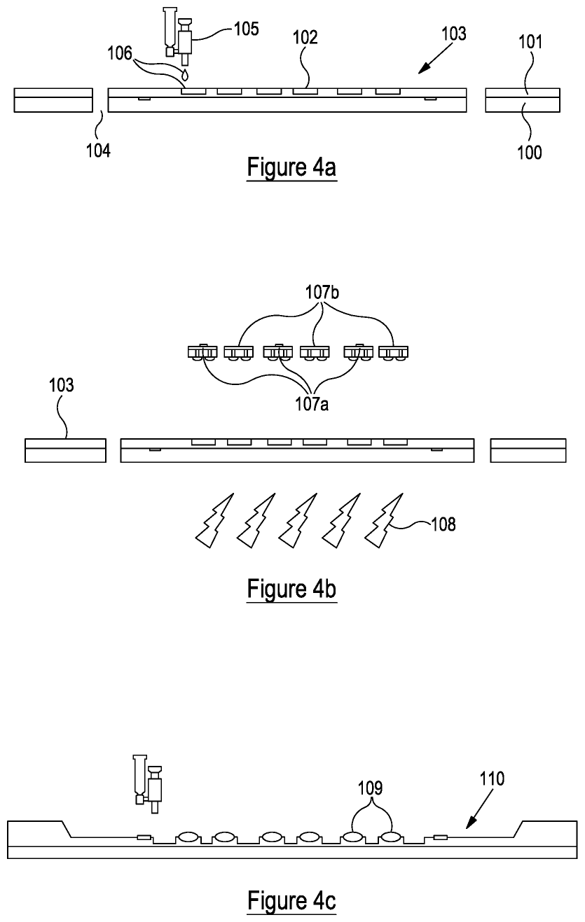

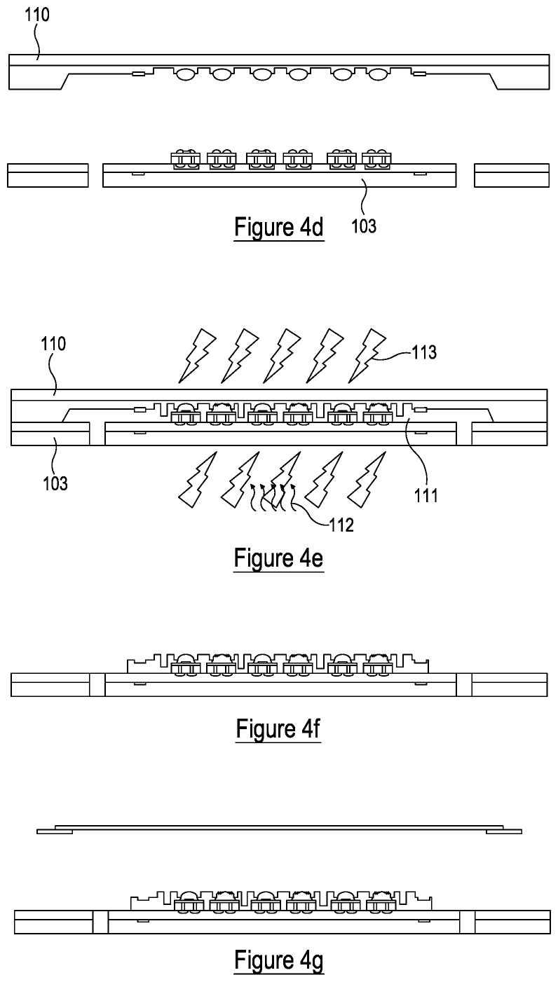

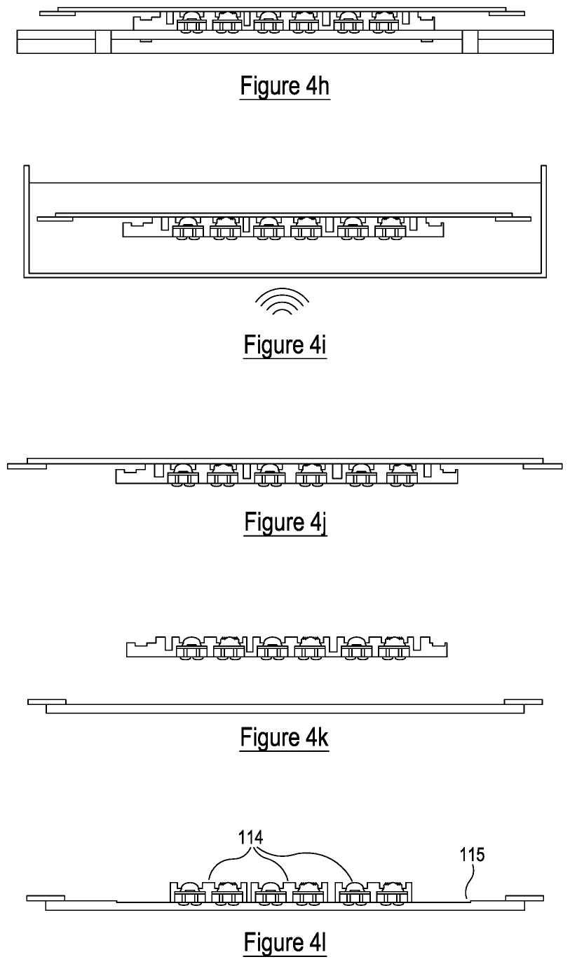

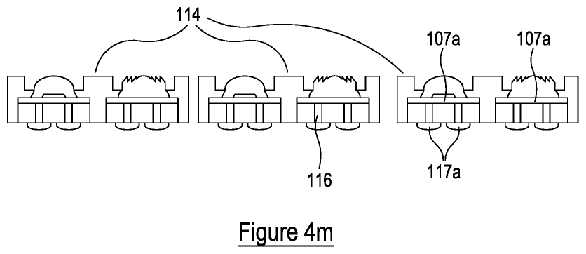

FIGS. 4a to 4m illustrate a process for producing dual component optoelectronics devices each of which comprises one emitter and one receiver device.

FIG. 4a illustrates a planar glass carrier 100 on which is provided a patterned layer of polydimethylsiloxane (PDMS) 101. As is the case with the first described embodiment, the pattern may be a one or two dimensional array of wells 102 formed in the PDMS layer 101. The carrier 100 and PDMS layer 101 are again referred to collectively hereinafter as the “first carrier” 103. Holes 104 extend through the first carrier in order to facilitate the injection molding process. FIG. 4a illustrates the use of a jetting tool 105 to inject a water soluble adhesive 106 into each of the wells.

As we are concerned here with dual component optoelectronics devices, pairs of previously singulated devices (emitters and receivers) 107a,107b are arranged in an array over the prepared first carrier 100—FIG. 4b—and lowered into place and the adhesive set by exposure to UV radiation 108.

The lenses or other passive optical components 109 are formed on a second carrier 110 using a process similar to that already described with respect to FIG. 2c, although in this case it may be that alternate lenses have different properties defined by respective molds in order to be adapted to the specific components over which they are to be located. The first and second carriers 103,110 are aligned as shown in FIG. 4d and subsequently brought into contact such that the passive optical components 109 are in contact with respective optical components 107a,107b. The lens compound is then cured using UV radiation such the lenses 109 adhere to respective optoelectronics components.

Polymer 111 is injected into the cavity formed between the first and second carriers through one of the holes 104 as shown in FIG. 4e and cured using UV radiation followed by heating 112,113.

The process steps illustrated in FIGS. 4e to 41 are analogous to those described with respect to FIG. 2 and result in the encapsulated optoelectronic device pairs 114 fixed to an adhesive tape 115, with the first and second carriers 103,110 removed. The singulated optoelectronics devices 114 are shown in FIG. 4m. This Figure illustrates more clearly the through chip vias 116 that enable electrical communication between the solder bumps 117 and contacts of the individual optoelectronics components (emitter 107a and receiver 107b).

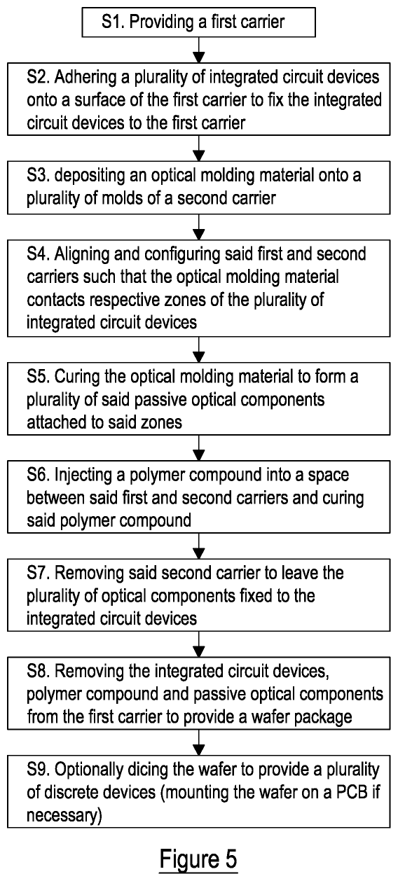

FIG. 5 is a flow diagram illustrating steps (S1 to S9) of the fabrication process.

The embodiments described above are concerned with the packaging of optoelectronics devices on silicon with through silicon vias connecting the circuits to the solder bumps. An alternative connection technology involves the fixing of the circuits to Printed Circuit Boards (PCBs) with vias extending through the PCBs to couple the circuits to solder bumps provided on the bases of the PCBs.

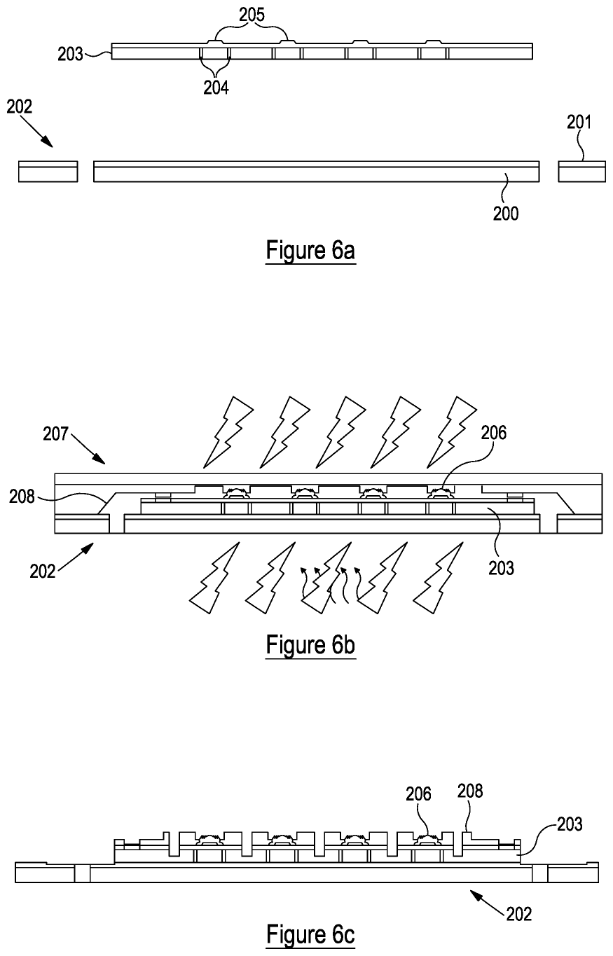

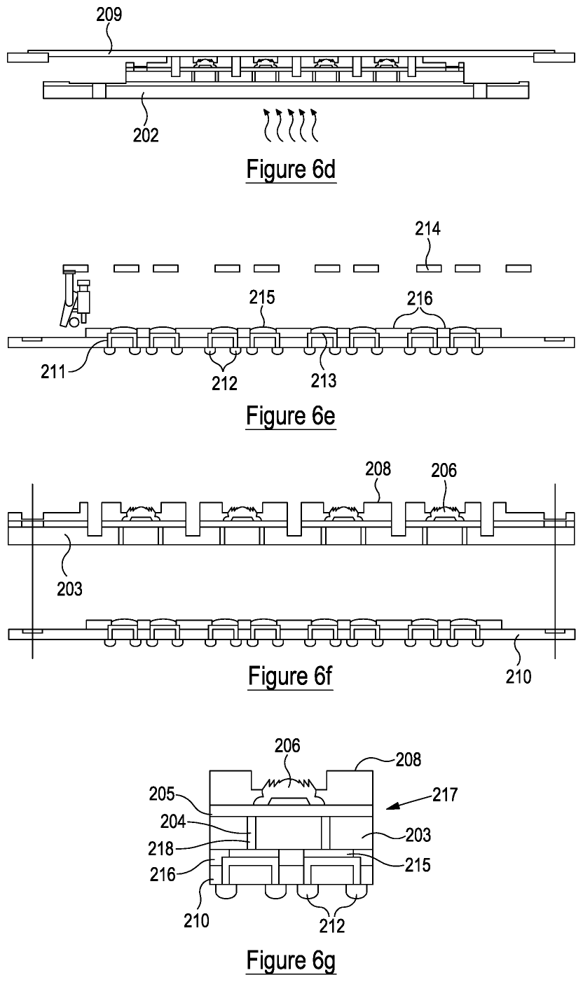

FIGS. 6a to 6g illustrate selected steps in the process of fabricating an exemplary single optoelectronics component device. FIG. 6a illustrates a planar glass substrate 200 overlaid with a layer of adhesive tape 201 to provide a first carrier 202. A silicon wafer 203 with through substrate vias 204 is also shown, with an array of optoelectronics components 205 fabricated thereon. The wafer and first carrier are aligned and the two brought into contact (not shown).

As with the previously described processes, an array of passive optical components 206 are formed using a second carrier 207 and the first and second carriers brought into contact as shown in FIG. 6b. The lens compound is then cured and polymer 208 is injected into the cavity formed between the two carriers and is allowed to set. The second carrier 207 is then removed and the remaining structure laser etched to cut through the polymer 208 between the optoelectronics components 205 and partially through the silicon wafer 203. The resulting structure is shown in FIG. 6c. An adhesive tape 209 is then attached to the upper surface of the structure as shown in FIG. 6d in preparation for removal of the first carrier 202 as described previously.

FIG. 6e illustrates a prefabricated PCB 210 with through PCB vias 211 connecting solder bumps 212 on the base of the PCB to copper pads 213 on the upper surface. A screen printing process, using a stencil 214, is used to selectively print a conductive adhesive 215 onto the copper pads 213 as well as a non-conductive adhesive 216 onto the areas between the copper pads. FIG. 6f shows the alignment of the structure comprising the silicon wafer 203 and the PCB 210. The two components are brought into contact and the conductive and non-conductive adhesives cured to fix the components together. The resulting composite structure is then diced to provide a plurality of single optoelectronics component devices 217, one of which is illustrated in FIG. 6g. For clarity, the drawing of FIG. 6g points out the optoelectronics component 205, passive optical component 206, silicon wafer (portion) 203, polymer 208, conductive adhesive 215, substrate vias 204, PCB 210, solder bumps 212, copper pads 212, and non-conductive adhesive 216. Also pointed out is the conductive metal 218 filling the substrate vias.

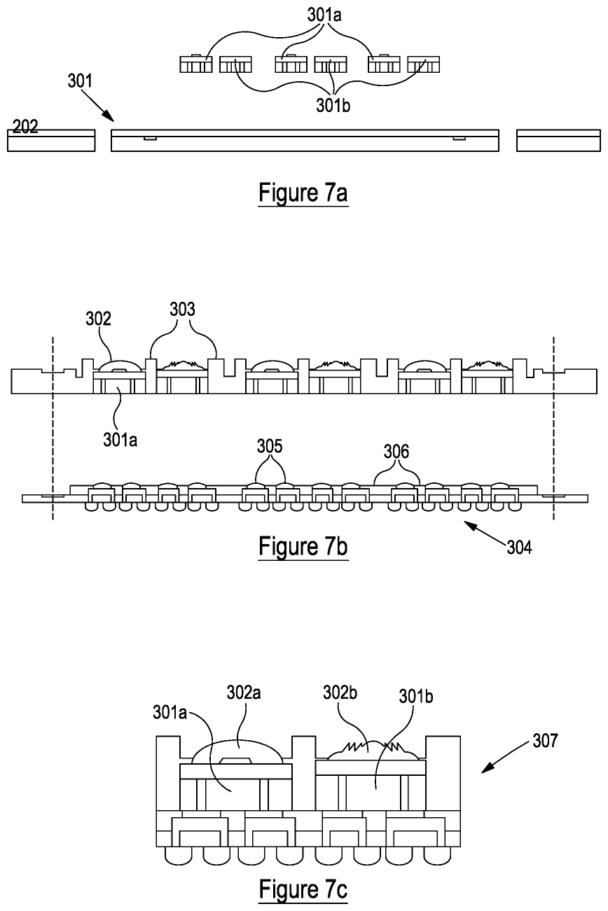

A process for fabricating dual components devices is illustrated in FIGS. 7a to 7c, again using PCBs with through vias. Only certain steps are shown as the process follows closely that of FIGS. 6a to 6g, except that discrete optoelectronics components 300a,300b of two different types (e.g. emitter and receiver) are alternately attached—FIG. 7a—to the first carrier 301 as an initial step. FIG. 7b illustrates the step of attaching the components 301a,301b, with lenses 302 attached and coupled by polymer 303, to the PCB 304 using conductive 305 and non-conductive 306 adhesive.

FIG. 7c illustrates the final, dual component optoelectronics device 307 with first and second different optoelectronic components 301a,301b. This figure also illustrates two different types of lens structures 302a,302b.

It will be appreciated by those of skill in the art that various modifications may be made to the above described embodiments without departing from the scope of the present invention.

1. A method of fabricating one or more optoelectronic devices each comprising at least one passive optical component, the method comprising:
(a) providing a first carrier;
(b) adhering a plurality of integrated circuit devices onto a surface of the first carrier to fix the integrated circuit devices to the first carrier;
(c) depositing an optical molding material onto a plurality of molds of a second carrier;
(d) aligning and configuring said first and second carriers such that the optical molding material contacts respective zones of the plurality of integrated circuit devices;
(e) curing the optical molding material to form a plurality of said passive optical components attached to said zones;
(f) injecting a polymer compound into a space between said first and second carriers and curing said polymer compound;
(g) removing said second carrier to leave the plurality of optical components fixed to the integrated circuit devices; and
(h) removing the integrated circuit devices, polymer compound and passive optical components from the first carrier to provide a wafer package.

2. A method according to claim 1, wherein step (b) comprises adhering said plurality of integrated circuit devices onto said surface of the first carrier using an adhesive, for example a soluble adhesive, or an adhesive tape, optionally wherein said adhesive is a water soluble adhesive and the method comprises, following step (h), removing the adhesive, or any residual adhesive, using water.

3. (canceled)

4. A method according to claim 1, wherein said plurality of integrated circuits are optoelectronic components of the same or different types.

5. A method according to claim 1 and comprising, after step (h), dicing the wafer package to provide a plurality of said optoelectronic devices.

6. A method according to claim 1, wherein said plurality of integrated circuits are mechanically and electrically coupled to a first surface of a planar substrate, for example a silicon substrate, with solder bumps provided on an opposed second surface of the substrate and through substrate vias to provide electrical coupling between the solder bumps and the integrated circuits, and step (b) comprises abutting said second surface against said surface of the first carrier so that the solder bumps are in contact with a soluble adhesive.

7. A method according to claim 6, said surface of the first carrier defining a plurality of wells into which said soluble adhesive is deposited.

8. A method according to claim 1 and comprising, after step (h), attaching the wafer package to a first surface of a Printed Circuit Board, PCB, to provide a composite structure, the PCB being provided with solder bumps on a second, opposed surface of the PCB and through PCB vias for electrically coupling the solder bumps to said first surface and thereby to integrated circuit devices of the wafer package.

9. A method according to claim 8 and comprising using a conductive adhesive on conductive pads, provided on said first surface of the PCB, and a non-conductive adhesive on other areas of the first surface, to attach the wafer package to the PCB.

10. A method according to claim 8, wherein said plurality of integrated circuits are mechanically and electrically coupled to a first surface of a planar substrate, for example a silicon substrate, with through substrate vias providing electrical coupling between said integrated circuit components and said PCB.

11. A method according to claim 8 and comprising, after attaching the wafer package to the PCB, dicing the composite structure to provide a plurality of said optoelectronic devices.

12. A method according to claim 1 and comprising, between steps (g) and (h), scribing said polymer compound between the integrated circuit devices.

13. A method according to claim 1, wherein said passive optical components are optical lenses.

14. A method according to claim 1, wherein said polymer compound at least partially surrounds the passive optical components to provide additional mechanical support for those components.

15. A discrete optoelectronics device comprising:
at least one integrated circuit device;
a substantially planar substrate having a first surface to which the or each optoelectronics component is fixed;
one or more solder bumps located on a second, opposed surface of the substrate and being electrically coupled to the or each optoelectronics component through said substrate;
one or more passive optical components adhered to a surface of the or each integrated circuit device; and
a polymer partially surrounding the or each integrated circuit device above the substrate.

16. A discrete optoelectronics device according to claim 15 and comprising two integrated circuit devices, one being a light emitter and one being a light receiver, such that the two integrated circuit devices are held together by said polymer.

17. A discrete optoelectronics device according to claim 15 and comprising two or more passive optical components having different optical properties.

18. A discrete optoelectronics device according to claim 15, wherein said polymer provides mechanical coupling of the or each optoelectronics component to the substrate.

19. A discrete optoelectronics device according to claim 15, wherein said substrate comprises a silicon substrate with said first and second surfaces being surfaces of the silicon substrate.

20. A discrete optoelectronics device according to claim 15, wherein said substrate comprises a silicon substrate providing said first surface and a Printed Circuit Board, PCB, fixed to an opposed surface of the silicon substrate, said second surface being an opposed surface of the PCB.

21. A discrete optoelectronics device produced using the method of claim 1.
